(19) United States
(12) Patent Application Publication
(10) Pub. No.: US 2018/0157110 A1
(43) Pub. Date: Jun. 7, 2018

(54) DISPLAY DEVICE

(71) Applicant: Samsung Display Co., Ltd., Yongin-si (KR)

(72) Inventor: Jeong Min Park, Yongin-si (KR)

(21) Appl. No.: 15/831,542

(22) Filed: Dec. 5, 2017

(30) Foreign Application Priority Data
Dec. 5, 2016 (KR) 10-2016-0164625

(51) Int. Cl. G02F 1/1335; G02F 1/1333; H01L 51/52; G02B 5/30

(52) U.S. Cl. CPC G02F 1/133528; G02F 1/133308; G02F 1/13338; G02B 27/286; H01L 51/5293; G02B 5/3025; G02F 2202/28; H01L 51/5246

(57) ABSTRACT

A display device is provided. In the display device, a transparent adhesive layer is disposed between a polarizing layer and a window. The transparent adhesive layer has a planar size smaller than that of the polarizing layer. In addition, a reinforcing member is disposed on a back surface of the window, which corresponds to a non-display area of a first substrate of the display device.

This application claims priority to Korean Patent Application No. 10-2016-0164625, filed on Dec. 5, 2016, and all the benefits accruing therefrom under 35 U.S.C. § 119, the contents of which in their entirety are herein incorporated by reference.

### BACKGROUND

### 1. Field

One or more embodiment of the present disclosure relates to a display device, and more particularly, to a display device having improved durability against impact or deformation.

### 2. Description of the Related Art

Liquid crystal displays (“LCD”s) that display characters and images using electro-optical characteristics of liquid crystals have excellent color reproduction and low power consumption, and can be manufactured to be thin. Thus, the liquid crystal displays are widely used for televisions, personal computers, potable terminals, and the like.

Organic light emitting display devices (“OLED”s) using self-luminescent characteristics of organic light emitting diodes have excellent visibility, can become be light in weight and thin in thickness, and can be driven at low voltage. Thus, the OLEDs have come into the spotlight as next-generation display devices.

### SUMMARY

Embodiments provide a display device having improved durability against impact or deformation.

Embodiments also provide a display device capable of reducing or effectively preventing degradation of reliability, caused by impact or deformation.

According to an embodiment of the present disclosure, there is provided a display device including: a first substrate including a display area in which an image is displayed and a non-display area at a periphery of the display area; a pixel array disposed on the display area of the first substrate; an input pad unit disposed on the non-display area of the first substrate, the input pad unit being electrically connected to the pixel array; a second substrate disposed facing the first substrate including the pixel array; a sealant disposed between the first substrate and the second substrate to surround the pixel array; a polarizing layer disposed on the second substrate; a window disposed on the polarizing layer; a transparent adhesive layer disposed between the polarizing layer and the window to bond the polarizing layer to the window, the transparent adhesive layer having a planar size smaller than that of the polarizing layer.

The pixel array may include a plurality of pixels. Each pixel may include: a first electrode; a second electrode disposed opposite to the first electrode; and a liquid crystal layer disposed between the first electrode and the second electrode. Alternatively, each pixel may include: a first electrode; a second electrode disposed opposite to the first electrode; and an organic emitting layer disposed between the first electrode and the second electrode.

The second substrate may include a transparent glass substrate or a transparent plastic substrate.

The polarizing layer may have the same planar size as the second substrate. The polarizing layer may have a pencil hardness of about 2H to about 6H.

The input pad unit may include a plurality of input pads arranged in a first direction. Each of the polarizing layer and the transparent adhesive layer may include a first side and a second side which face each other in the first direction. A length of the first side and the second side of the transparent adhesive layer in a second direction crossing the first direction may be less than that of the first side and the second side of the polarizing layer.

Each of the polarizing layer and the transparent adhesive layer may further include a third side and a fourth side which face each other in the second direction. Side surfaces of the polarizing layer at the first side, the second side and the third side thereof may be respectively coplanar with side surfaces of the transparent adhesive layer at the first side, the second side and the third side thereof.

In the top plan view, the input pad unit may be disposed adjacent to the fourth side of the polarizing layer and the fourth side of the transparent adhesive layer, a portion of the polarizing layer at the fourth side thereof may be exposed from the transparent adhesive layer, and the fourth side of the transparent adhesive layer may be located inside of the sealant.

The sealant may include polymer resin or frit.

The window bonded to the polarizing layer may include a reinforcing member disposed on a back surface of the window to correspond to the non-display area of the first substrate. The reinforcing member may be attached to the back surface of the window by an adhesive member.

The reinforcing member may correspond to the input pad unit disposed in the non-display area of the first substrate. The reinforcing member may include carbon steel or stainless steel.

The display device may further include a driving circuit unit electrically connected between the input pad unit and the pixel array to receive the driving signal from the input pad unit and provide the received driving signal to the pixel array, and a plurality of conductive lines which electrically connect the driving circuit to the input pad unit and the pixel array.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

FIG. 1 is an exploded perspective view illustrating an embodiment of a display device according to the invention.

FIG. 2 is a top plan view illustrating the display device of FIG. 1.

FIG. 3 is an exploded cross-sectional view illustrating an embodiment of a pixel array including a pixel.

FIG. 4 is an enlarged cross-sectional view illustrating another embodiment of a pixel in a pixel array of a display device.

FIG. 5 is a cross-sectional view taken along line A1-A2 of FIG. 2.

FIG. 6 is a cross-sectional view taken along line B1-B2 of FIG. 2.

FIG. 7 is a cross-sectional view illustrating another embodiment of a display device according to the invention.

FIG. 8 is a graph illustrating results obtained by performing a drop reliability test on display devices according to embodiments of the present disclosure.

### DETAILED DESCRIPTION

Hereinafter, exemplary embodiments of the present disclosure will be described with reference to the accompanying drawings. However, it is to be understood by those skilled in the art that various modifications can be made in the following embodiments of the invention, and the scope of the invention is not limited to the following embodiments.

In the drawing figures, dimensions may be exaggerated for clarity of illustration. Like reference numerals refer to like elements throughout. Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being related to another element such as being “on,” “between” or “connected to” another element, it can be directly on the other element or intervening elements may be present therebetween. In contrast, when an element is referred to as being related to another element such as being “directly on,” “directly between” or “directly connected to” another element, there are no intervening elements present. As used herein, “connected” may refer to a physical, electrical and/or thermal connection between elements.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Display devices such as liquid crystal displays (“LCD”s) and organic light emitting display devices (“OLED”s) are generally manufactured using a relatively thin glass substrate. The glass substrate having relatively high transmittance is suitable as a material of the display devices, but is easily damaged even due to a small impact or deformation.

Overall thicknesses of display devices have been reduced which an overall size of the display devices has increased. In order to decrease the thicknesses of the display devices, the thickness of a glass substrate may be decreased. A relatively thin glass substrate have a maximum thickness of about 0.5 millimeter (mm) or less is easily deformed such as to be curved. However, such a deformable thin glass substrate is very weak against impact thereto, and therefore, the durability of the thin glass substrate is problematic.

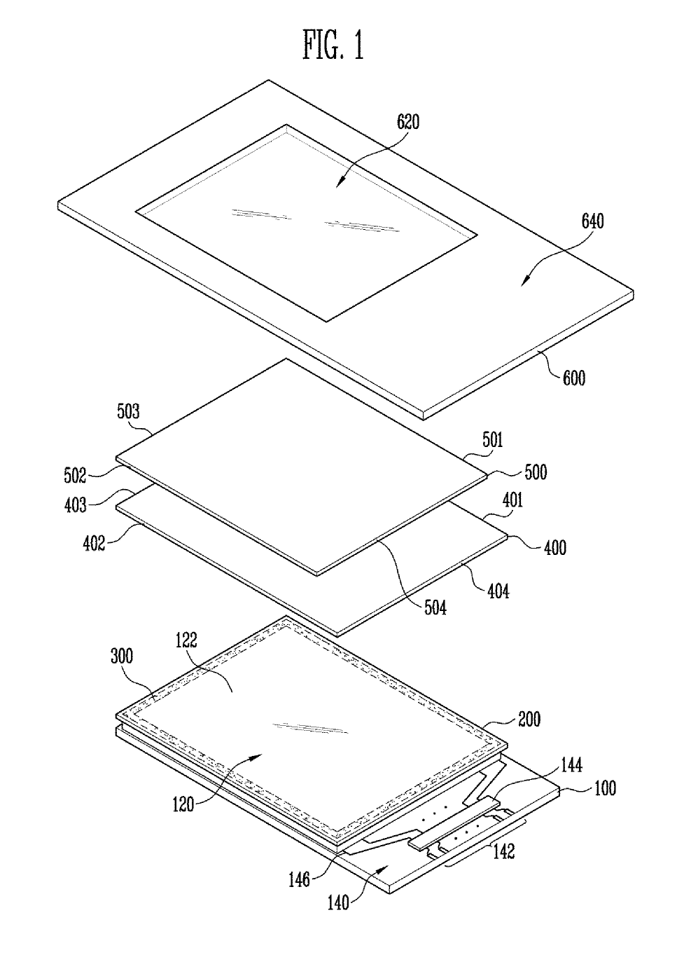

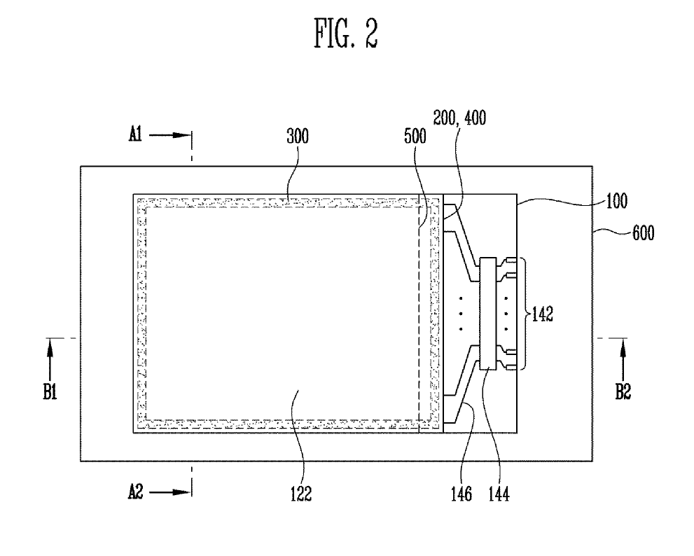

FIG. 1 is an exploded perspective view illustrating an embodiment of a display device according to the invention. FIG. 2 is a top plan view illustrating the display device of FIG. 1. A configuration of the display device according to the embodiment will be schematically described.

Referring to FIGS. 1 and 2, a lower display substrate including a first (base) substrate 100 includes a display area 120 in which an image is displayed, and a non-display area 140 at the periphery of the display area 120 and at which the image is not displayed. In an embodiment, for example, the non-display area 140 may be disposed to surround the periphery of the display area 120, such as at all sides of the display area 120.

The first substrate 100 may be configured as a transparent glass substrate or a transparent plastic substrate.

A pixel array 122 is disposed at the display area 120 of the first substrate 100 such as on the base substrate thereof.

The pixel array 122 may include a gate line provided in plurality and a data line provided in plurality, which are arranged to intersect each other. A pixel is provided in plurality respectively connected, for example, in a matrix form between the plurality of gate lines and the plurality of data lines.

FIG. 3 is an exploded cross-sectional view illustrating an embodiment of the pixel array including a pixel.

The pixel may include a first electrode, a second electrode disposed opposite to the first electrode, and an optical control layer such as a liquid crystal layer interposed between the first electrode and the second electrode.

Referring to FIG. 3, a gate line 111 provided in plurality and a data line 112 provided in plurality are arranged at the display area 120 of the first substrate 100 to intersect each other. A pixel electrode 115 provided in plurality as first electrodes are arranged in a matrix form in respective pixel areas 113. In one embodiment, the pixel or the pixel areas 113 may be defined by the gate lines 111 and the data lines 112, which intersect each other, but the invention is not limited thereto.

A switching element such as a thin film transistor 114 for transmitting a signal to the pixel electrode 115 may be disposed or formed on the first substrate 100, such as on the base substrate thereof. The thin film transistor 114 is connected to the pixel electrode 115. In one embodiment, the thin film transistor 114 may be disposed at a portion at which the gate line 111 and the data lines 112 intersect each other, but the invention is not limited thereto.

A color filter 211 and a common electrode 212 as a second electrode of an upper display substrate are disposed or formed on a second (base) substrate 200 corresponding to the display area 120.

An optical control layer such as a liquid crystal layer 250 is interposed between the pixel electrode 115 and the common electrode 212. The lower display substrate, the upper display substrate and the liquid crystal layer 250 may together form a display panel of the display device. The display panel displays an image with light. The display device may have a relatively long side lengthwise extended in a first direction and a relatively short side lengthwise extended in a second direction which crosses the first direction. The display device and components thereof may be disposed in a plane parallel to that defined by the first and second directions. A third direction which crosses each of the first and second directions defined in a thickness direction of the display device and component thereof.

A backlight unit (not shown) including a light source configured as, for example, a light emitting diode or the like may be disposed on the bottom of the first substrate 100. The backlight unit generates and provides the light to the display panel to display the image.

An electric field between the pixel electrode 115 and the common electrode 212, which corresponds to each pixel, is controlled according to a driving signal provided to the pixel array 122, so that the alignment direction of the liquid crystal layer 250 is controlled. Accordingly, the transmittance of light provided from the backlight unit is controlled, so that an image can be displayed by the display panel through the second substrate 200 to a viewing side of the display device.

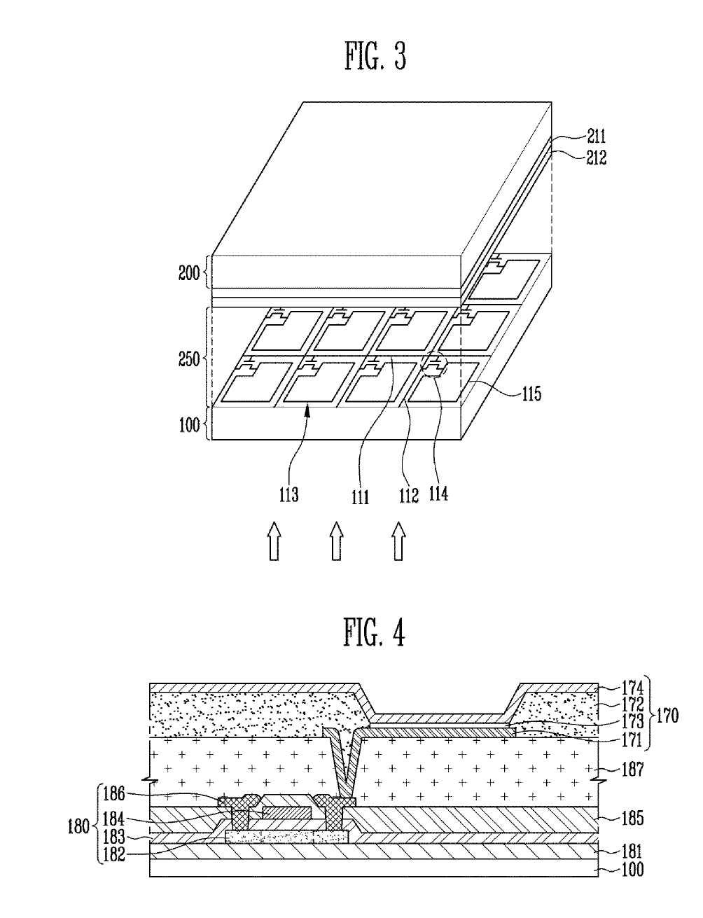

FIG. 4 is an enlarged cross-sectional view illustrating an embodiment of a pixel in a pixel array of a display device.

The pixel may include a first electrode, a second electrode disposed opposite to the first electrode, and an organic emitting layer interposed between the first electrode and the second electrode.

Referring to FIG. 4, the pixel may include an organic light emitting diode 170 disposed or formed on the first substrate 100, and a thin film transistor 180 for transmitting a driving or control signal and a capacitor (not shown) for maintaining a drive or control signal may be connected to the organic light emitting diode 170.

The organic light emitting diode 170 includes a first electrode 171, a second electrode 174 disposed opposite to the first electrode 171, and an organic emitting layer 173 interposed between the first electrode 171 and the second electrode 174. The organic emitting layer 173 is disposed or formed on the first electrode 171 of an opening (a light emission region) defined by a pixel defining layer 172, and may further include a hole injection layer, a hole transport layer, an electron transport layer and an electron injection layer.

The thin film transistor 180 includes a semiconductor layer 182 that provides a source region, a drain region and a channel region, a gate electrode 184 insulated from the semiconductor layer 182 with a gate insulating layer 183 interposed therebetween, and source and drain electrodes (left and right 186) electrically connected to the source and drain regions of the semiconductor layer 182 at contact holes in an insulating layer 185 and the gate insulating layer 183. Reference numeral 181 designates a buffer layer, and reference numeral 187 designates a planarization insulating layer.

Referring again to FIGS. 1 and 2, an input pad unit 142 of a display panel includes a plurality of input pads. The input pad unit 142 is electrically connected to the pixel array 122 through a conductive signal line 146 provided in plurality. The input pad unit 142 and the lines 146 are disposed at the non-display area of the first substrate 100. A flexible printed circuit board (“FPCB”) (not shown) that provides power and signals from outside the display panel may be electrically connected to the input pad unit 142. The pixel array 122 of FIGS. 1 and 2 may include any one of the pixels illustrated in FIGS. 3 and 4.

A driving circuit unit 144 may be disposed between the pixel array 122 and the input pad unit 142. Input and output terminals of the driving circuit unit may be electrically connected to the input pad unit 142 and the pixel array 122 through the lines 146, respectively. Although the lines 146 are labeled between the driving circuit unit 144 and the pixel array 122, lines (unlabeled in FIGS. 1 and 2 are also disposed between the driving circuit unit 144 and the input pad unit 142. The driving circuit unit 144 receives power and signals, which are provided from the outside the display panel, through the input pad unit 142, and outputs a driving signal for driving the pixel array 122.

In an embodiment, the second substrate 200 is disposed on the top of the first substrate 100 including the pixel array 122, and a sealant 300 is disposed between the first substrate 100 and the second substrate 200 to surround the pixel array 122. The second substrate 200 and the sealant 300 may collectively define an encapsulation member which encapsulates the pixel array 122 on the first substrate 100.

The second substrate 200 may be configured as a transparent glass substrate or a transparent plastic substrate. The second substrate 200 may be disposed on the top of the first substrate 100 to include the display area 120 and a portion of the non-display area 140. A non-display area may include an area of the first and second substrates 100 and 200 at which the sealant 300 is disposed and extend to an end or edge of the larger of the first and second substrate 100 and 200, such as to the end of the first substrate 100 at which the input pad unit 142 is disposed.

The sealant 300 seals the pixel array 122 and allows the first substrate 100 and the second substrate 200 to be bonded to each other. In an embodiment of manufacturing a display device, the sealant 300 may be formed by applying polymer resin or frit and then curing the polymer resin or frit using heat, ultraviolet, infrared, laser, etc.

A polarizing layer 400 is disposed on the second substrate 200, and a transparent adhesive layer 500 is disposed on the polarizing layer 400. The polarizing layer 400 may be in contact with and/or attached to the second substrate 200. The polarizing layer 400 may be attached to the first substrate 100, such as via other elements like the second substrate 200, the sealant 300, etc. The encapsulation member may be considered as further including the polarizing layer 400 on the second substrate 200 and the sealant 300. A display panel may be considered as further including the polarizing layer 400 on the second substrate 200 and/or the encapsulation member.

The polarizing layer 400 is used to convert incident light into polarized light. The polarizing layer 400 may have a relatively high hardness, e.g., a pencil hardness of about 2H to about 6H so as to maintain durability and mechanical strength. The polarizing layer 400 may include or be formed of, for example, a polymer material such as polyvinyl alcohol (“PVA”).

In an embodiment of manufacturing a display device, the transparent adhesive layer 500 may be formed by applying a polymer resin material that is optically transparent and has adhesion relative to a material of the polarizing layer 400, and then pre-curing the polymer resin material using heat, infrared, etc. In order to allow the visibility of the transparent adhesive layer 500 not to be lowered, the transparent adhesive layer 500 includes or is formed of a material that has a refractive index similar to those of the polarizing layer 400 disposed on the bottom thereof and a window 600 disposed on the top thereof or that minimizes a difference relative to the refractive indices with the polarizing layer 400 and the window 600.

The input pads of the input pad unit 142 are arranged spaced apart from each other in one (second direction). The polarizing layer 400 may include, for example, a first side 401 and a second side 402, which face each other in the second direction, and a third side 403 and a fourth side 404, which face each other in the first direction. The transparent adhesive layer 500 may include, for example, a first side 501 and a second side 502, which face each other in the second direction, and a third side 503 and a fourth side 504, which face each other in the first direction.

The polarizing layer 400 has the same planar size as the second substrate 200, but the transparent adhesive layer 500 may have a planar size smaller than that of the polarizing layer 400. Referring to the dotted line in FIG. 2 indicating the fourth side 504 of the transparent adhesive layer 500, for example, an overall length of the first side 501 and the second side 502 of the transparent adhesive layer 500 in the first direction may be less than that of the first side 401 and the second side 402 of the polarizing layer 400 in the first direction.

The window 600 is disposed on the transparent adhesive layer 500 to overlap an entirety of the first substrate 100. The window 600 may be attached on the polarizing layer 400 by adhesion of the transparent adhesive layer 500 between the window 600 and the polarizing layer 400. The window 600 may form an outer surface of the display device at the viewing side thereof.

The window 600 may include a transmission area 620 corresponding to the display area 120 in which the image is displayed, and a blocking area 640 at the periphery of the transmission area 620. Light and/or the image from the display area 120 may be transmitted at the transmission area 620, while light and/or the image is blocked at the blocking area 640. Also referred to as a black matrix area, the blocking area 640 is used to allow the non-display area 140 except the display area 120 not to be viewable at the viewing side of the display device. The overall window 600 may include or be made of, for example, glass, plastic, or the like as a base substrate thereof. A material or film which blocks light, such as having a black color, may be applied in the black matrix area 640 of the base substrate.

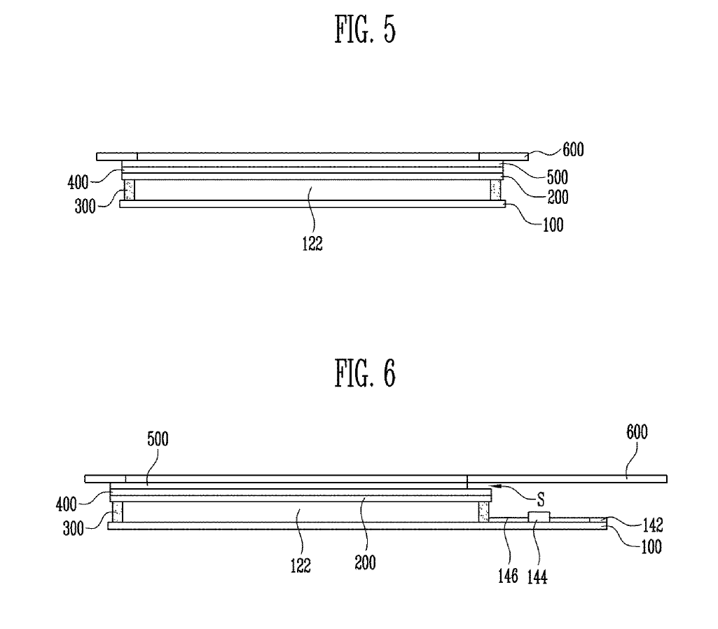

FIG. 5 is a cross-sectional view taken along line A1-A2 of FIG. 2. FIG. 5 is a view of the thickness direction (e.g., third direction) of the display device and of constituent elements thereof.

Since the polarizing layer 400 has the same size as the second substrate 200 in both the first and the second directions, side surfaces of the first to fourth sides 401 to 404 of the polarizing layer 400 may respectively correspond to those of the four sides of the second substrate 200. The first to fourth sides 401 to 404 of the polarizing layer 400 may be coplanar with or aligned with the first to fourth sides of the second substrate 200.

The transparent adhesive layer 500 has a size smaller than that of the polarizing layer 400 in the first direction, but side surfaces of the first to third sides 501 to 503 of the transparent adhesive layer 500 may respectively correspond to those of the first to third sides 401 to 403 of the polarizing layer 400. The first to third sides 501 to 503 of the transparent adhesive layer 500 may be coplanar with or aligned with the first to third sides 401 to 403 of the polarizing layer 400.

In an embodiment of manufacturing a display device, for example, if the polarizing layer 400 and the transparent adhesive layer 500 are sequentially formed on the second substrate 200 of a mother substrate including a plurality of individual display devices and then cut along a scribe line to separate the display devices from the mother substrate, the side surfaces of the first to third sides 501 to 503 of the transparent adhesive layer 500 may correspond to (e.g., be aligned with) those of the first to third sides 401 to 403 of the polarizing layer 400.

FIG. 6 is a cross-sectional view taken along line B1-B2 of FIG. 2. FIG. 6 is a view of the thickness direction (e.g., third direction) of the display device and of constituent elements thereof.

Since the transparent adhesive layer 500 has a size smaller than that of the polarizing layer 400 in the first direction, a side surface at the fourth side 504 of the transparent adhesive layer 500 may not correspond to that of the fourth side 404 of the polarizing layer 400. A partial region of the polarizing layer 400 at the fourth side 404 thereof, which is adjacent to the input pad unit 142, may be exposed from the transparent adhesive layer 500. The fourth side 504 of the transparent adhesive layer 500, which is adjacent to the input pad unit 142, may not overlap with the sealant 300. In an embodiment, for example, the fourth side 504 of the transparent adhesive layer 500 may be disposed at the inside of the sealant 300.

The position of the fourth side 504 of the transparent adhesive layer 500 is controlled such that the polarizing layer 400 is not viewable through the transmission area 620 of the window 600.

The display device configured as described above may be assembled such that the black matrix area 640 as a peripheral area of the window 600 is supported by a mold frame (not shown) and a back surface of the first substrate 100 is mounted in a chassis frame (not shown), and then be mounted in a case (not shown).

As described above, in one or more embodiment of the present disclosure, the polarizing layer 400 is disposed on the second substrate 200, such as at a viewing side of the display device. In this case, the polarizing layer 400 has the same size of the second substrate 200 through which an image is transmitted.

The polarizing layer 400 has the form of a relatively high-hardness thin film, and is disposed between the second substrate 200 and the window 600.

When an impact or force is applied at the window 600, deformation of the window 600 is reduced or effectively prevented by the self-hardness of the polarizing layer 400, so that the transfer of a force to other elements of the display device due to the impact or deformation to the window 600 can be reduced. Since the force to the window 600 is not transferred to the second substrate 200 or the sealant 300, a failure of components within a display panel caused by damage of the second substrate 200 or the sealant 300 can be effectively prevented.

In particular, when the second substrate 200 is configured as a glass substrate having a thickness of about 0.5 millimeter (mm) or less, the brittleness of the second substrate 200 may be relatively high. As used herein, the thickness of the second substrate 200 may be a maximum thickness thereof. However, according to one or more embodiment of the present disclosure, damage to the second substrate 200 or components within the display panel caused by a force or impact to the window 600 may be reduced or effectively prevented. The force due to the impact or deformation may include pressure or stress.

The deformation of the window 600 can be reduced or effectively prevented as the thickness of the polarizing layer 400 increases. However, since a total thickness of the display device increases as the thickness of the polarizing layer 400 increases, the thickness of the polarizing layer 400 is selected within an appropriate range by considering the thickness of the second substrate 200, the thickness of the window 600, and the like.

In one or more embodiment of the present disclosure, the transparent adhesive layer 500 is disposed on the polarizing layer 400. In this case, the transparent adhesive layer 500 has a planar size smaller than that of the polarizing layer 400.

Referring to FIG. 6, the material of the transparent adhesive layer 500 has a predetermined viscosity and elasticity. When an impact is applied to the window 600 or when a deformation occurs in the window 600, a portion of a force due to the impact or deformation may be absorbed by the transparent adhesive layer 500, but a majority of the force may be transferred to the second substrate 200 and the sealant 300 through the polarizing layer 400.

However, according to one or more embodiment of the present disclosure, since the transparent adhesive layer 500 is not on or overlapping the sealant 300, the transfer of the force can be effectively blocked by a severance area (portion S) formed as an empty space. The polarizing layer 400 (and the second substrate 200) extend further than an edge or end of the transparent adhesive layer 500. The window 600 overlapping the transparent adhesive layer 500, extends further an edge or end of each of the transparent adhesive layer 500, the polarizing layer 400 and the second substrate 200. At these edges or ends, the window 600 faces an exposed portion of the polarizing layer 400, to form the portion S. Thus, since the force from the window 600 is not transferred to the sealant 300 at the portion S, a failure caused by damage of the sealant 300 can be effectively prevented.

In particular, when the sealant 300 includes or is made of frit, the frit may be easily damaged even by a relatively weak impact or deformation due to a relatively high brittleness of the frit. According to one or more embodiment of the present disclosure, damage of the sealant 300 due to the impact or deformation can be effectively reduced.

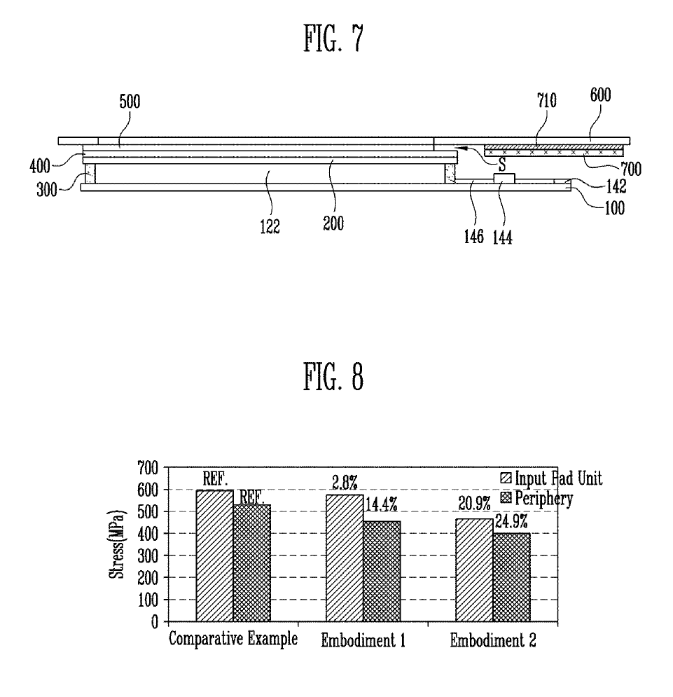

FIG. 7 is a cross-sectional view illustrating another embodiment of a display device according to the invention.

The display device according to the embodiment of FIG. 7 has a structure basically similar to that of the display device shown in FIG. 6, except for a reinforcing member 700 is further provided on a back surface of the window 600.

The reinforcing member 700 includes or is formed of a relatively high-strength alloy such as carbon steel or stainless steel (“SUS”), and may be attached to the back surface of the window 600 by an adhesive member 710 such as an adhesive or a double-sided tape.

The reinforcing member 700 may be disposed on the back surface of the window 600 corresponding to the non-display area 140 of the first substrate 100. The reinforcing member 700 may be disposed on an extended portion of the window 600 which extends further an edge or end of each of the transparent adhesive layer 500, the polarizing layer 400 and the second substrate 200. In an embodiment, for example, the reinforcing member 700 may be disposed to correspond to the pad unit 142 disposed in the non-display area 140 of the first substrate 100. Alternatively, the reinforcing member 700 may be disposed with a relatively wide area to have a total planar area corresponding to a total planar area occupied by the input pad unit 142 and the driving circuit unit 144, which are disposed in the non-display area 140 of the first substrate 100.

As described above, in one or more embodiment of the present disclosure, the reinforcing member 700 is disposed on the back surface of the window 600 corresponding to the non-display area 140.

When an impact is applied to the window 600 or when a deformation occurs in the window 600, the window 600 is supported by the reinforcing member 700 having a relatively high strength, so that the deformation of the window 600 is minimized. Simultaneously, a force due to the impact or deformation can be dispersed to the whole of the reinforcing member 700. Thus, owing to the portion S and the reinforcing member 700, since the force is relatively weakly transferred or is not transferred to the polarizing layer 400, the second substrate 200, the sealant 300 and the like, which are physically in relatively close contact with the window 600, a failure caused by damage of the second substrate 200 or the sealant 300 can be effectively prevented.

FIG. 8 is a graph illustrating results obtained by performing a drop reliability test on display devices according to embodiments of the present disclosure, relative to a comparative example.

In each of the Embodiment 1, Embodiment 2 and Comparative Example, left bar graphs represent stresses in the non-display area 140 adjacent to the input pad unit 142, and right bar graphs represent stresses in the non-display area 140 at the right periphery of the sealant 300.

The display device according to the embodiment (Embodiment 1) of FIG. 6 can obtain an effect that the stresses adjacent to the input pad unit 142 and at the right periphery of the sealant 300 of the display device are decreased by about 2.8% and 14.4%, respectively, as compared with a display device, as a comparative example (REF.), in which the transparent adhesive layer has the same size as the polarizing layer. The display device according to the embodiment (Embodiment 2) of FIG. 7 can obtain an effect that the stresses of the display device are decreased by about 20.9% and 24.9% as compared with the comparative example (REF.)

The display devices according to one or more embodiment of the present disclosure have relatively high durability due to the above-described structures, and accordingly, the reliability of the display devices can be improved.

According to one or more embodiment of the present disclosure, the transparent adhesive layer is disposed between the polarizing layer and the window. In this case, the transparent adhesive layer has a total planar size smaller than that of the polarizing layer. When an impact is applied to the window or when a deformation occurs in the window, the transparent adhesive layer is not disposed at an upper portion adjacent to the sealant, and hence the transfer of a force from the window to the polarizing layer or sealant due to the impact or deformation can be blocked by the severance area formed as an empty space.

Also, according to one or more embodiment of the present disclosure, a reinforcing member is disposed on the back surface of the window corresponding to the non-display area of the first substrate. When an impact is applied to the window or when a deformation occurs in the window, the window is supported by the reinforcing member, so that the deformation of the window is minimized, and simultaneously, a force due to the impact or deformation can be dispersed to the whole of the reinforcing member.

As described above, in one or more embodiment of the display device according to the present disclosure, since the force is weakly transferred or is not transferred to the polarizing layer, the second substrate, the sealant and the like, which are physically in relatively close contact with the window, the durability of the display device is relatively high, and accordingly, the reliability of the display device can be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display device comprising:
a first substrate including a display area in which an image is displayed and a non-display area at a periphery of the display area;
a pixel array disposed on the display area of the first substrate;
an input pad unit disposed on the non-display area of the first substrate, the input pad unit being electrically connected to the pixel array to provide a driving signal thereto;
a second substrate disposed facing the first substrate including the pixel array;
a sealant disposed between the first substrate and the second substrate to surround the pixel array;
a polarizing layer disposed on the second substrate;
a window disposed on the polarizing layer; and
a transparent adhesive layer disposed between the polarizing layer and the window to bond the polarizing layer to the window, the transparent adhesive layer having a planar size smaller than that of the polarizing layer.

2. The display device of claim 1, wherein the pixel array on the display area of the first substrate includes a plurality of pixels,
wherein each pixel includes:
a first electrode;
a second electrode disposed opposite to the first electrode; and
a liquid crystal layer disposed between the first electrode and the second electrode.

3. The display device of claim 1, wherein the pixel array on the display area of the first substrate includes a plurality of pixels,
wherein each pixel includes:
a first electrode;
a second electrode disposed opposite to the first electrode; and
an organic emitting layer disposed between the first electrode and the second electrode.

4. The display device of claim 1, wherein the second substrate includes a transparent glass substrate or a transparent plastic substrate.

5. The display device of claim 1, wherein the polarizing layer has a same planar size as the second substrate.

6. The display device of claim 1, wherein the polarizing layer has a pencil hardness of about 2H to about 6H.

7. The display device of claim 1, wherein in a top plan view,
each of the polarizing layer and the transparent adhesive layer includes a first side and a second side which face each other in a first direction, and
a length of the first side and the second side of the transparent adhesive layer in a second direction crossing the first direction, is less than that of the first side and the second side of the polarizing layer.

8. The display device of claim 7, wherein
each of the polarizing layer and the transparent adhesive layer further includes a third side and a fourth side, which face each other in the second direction,
side surfaces of the polarizing layer at the first side, the second side and the third side thereof are respectively coplanar with side surfaces of the transparent adhesive layer at the first side, the second side and the third side thereof.

9. The display device of claim 8, wherein in the top plan view,
the input pad unit is disposed adjacent to the fourth side of the polarizing layer and the fourth side of the transparent adhesive layer,
a portion of the polarizing layer at the fourth side thereof is exposed from the transparent adhesive layer, and
the fourth side of the transparent adhesive layer is located inside of the sealant.

10. The display device of claim 1, wherein the sealant includes polymer resin or frit.

11. The display device of claim 1, wherein the window bonded to the polarizing layer includes a reinforcing member disposed on a back surface of the window, the reinforcing member on the back surface of the window corresponding to the non-display area of the first substrate.

12. The display device of claim 11, wherein the reinforcing member is attached to the back surface of the window by an adhesive member.

13. The display device of claim 11, wherein the reinforcing member on the back surface of the window faces the input pad unit disposed on the non-display area of the first substrate.

14. The display device of claim 11, wherein the reinforcing member on the back surface of the window includes carbon steel or stainless steel.

15. The display device of claim 1, further comprising:
a driving circuit electrically connected between the input pad unit and the pixel array to receive the driving signal from the input pad unit and provide the received driving signal to the pixel array, and
a plurality of conductive lines which electrically connect the driving circuit to the input pad unit and the pixel array.

16. A display device, comprising:
a display panel comprising:
a first substrate including: a display area in which an image is displayed, and a non-display area disposed adjacent to the display area at a first side of the display panel,
a pixel array disposed on the first substrate in the display area thereof;
an encapsulation member which encapsulates the pixel array on the first substrate; and
a polarizing layer on the encapsulation member;
a window attached to the polarizing layer; and
a transparent adhesive layer disposed between the polarizing layer and the window to attach the polarizing layer to the window,
wherein at the first side of the display panel at which the non-display is disposed,
the window bonded to the polarizing layer, the polarizing layer, the encapsulation member and the first substrate extend further than an end of the transparent adhesive layer to respectively define extended portions of the window, the polarizing layer, the encapsulation member and the first substrate which are in the non-display area, and
in the non-display area disposed at the first side of the display panel, the extended portion of the window faces the extended portion of each of the polarizing layer, the encapsulation member and the first substrate.

17. The display device of claim 16, wherein the window bonded to the polarizing layer includes a reinforcing member disposed on a back surface of the window to face the extended portion of the first substrate.

18. The display device of claim 16, further comprising a driving circuit unit connected to the pixel array and through which a driving signal is provided to the pixel array to display the image, the driving circuit unit including a plurality of input pads on the first substrate in the non-display area thereof disposed at the first side of the display panel,
wherein the extended portion of the window faces the plurality of input pads of the driving circuit unit.

19. A method of forming a display device, comprising:
providing a display panel which displays an image with light, the display panel including a polarizing layer at a viewing side of the display device; and
attaching a window through which the image is viewed, to the display panel including the polarizing layer, by a transparent adhesive layer bonded to a back surface of the window,
wherein at a same side of the display device in a top plan view, the attaching the window disposes outer edges of each of the window and the display panel outside an outer edge of the transparent adhesive layer.

20. The method of claim 19, wherein
the window includes a reinforcing member on the back surface thereof, and
the attaching the window further disposes the reinforcing member to face the outer edge of the display panel.
